(19) United States
(12) Patent Application Publication
(10) Pub. No.: US 2005/0077629 A1
(43) Pub. Date: Apr. 14, 2005

(54) Photoresist ash process with reduced inter-level dielectric ( ILD) damage

(75) Inventors: Timothy J. Dalton, Ridgefield, CT (US); Nicholas C.M. Fuller, Elmsford, NY (US); Kaushik A. Kumar, Beacon, NY (US)

Correspondence Address: SCULLY SCOTT MURPHY & PRESSER, PC, 400 GARDEN CITY PLAZA, GARDEN CITY, NY, 11530, US

(73) Assignee: INTERNATIONAL BUSINESS MACHINES CORPORATION, ARMONK, NY (US)

(21) Appl. No.: 10/685,012

(22) Filed: Oct. 14, 2003

(51) Int. Cl. H01L 23/48

(52) U.S. Cl. 257/759

(57) ABSTRACT

Novel interconnect structures possessing an organosilicate dielectric material with unaltered physical and chemical properties post exposure to a specific resist ash chemistry for use in semiconductor devices are provided herein. The novel interconnect structure is capable of delivering improved device performance, functionality and reliability owing to the use of a chemically and physically “friendly” resist ash process. An in situ inert gas/H₂ process achieves minimal chemical and physical reactivity with the organosilicate sidewalls during ashing owing to its inherent make up.

### FIELD OF THE INVENTION

The present invention generally relates to integrated circuits (ICs), and more particularly to interconnect structures including, for example, multilevel interconnect structures, in which the original physical and chemical integrity of the dielectric is significantly retained by employing an ash process for photoresist removal post single and dual damascene processing that induces minimal physical and chemical modification of the etched sidewalls of an interlevel dielectric (ILD). The present invention is also significant for wafer de-fluorination post barrier (cap) removal during dual damascene processing.

### BACKGROUND OF THE INVENTION

Generally, semiconductor devices include a plurality of circuits that form an integrated circuit (IC) including chips (e.g., chip back-end-of-the-line, or “BEOL”), thin film packages and printed circuit boards. Integrated circuits can be useful for computers and electronic equipment and can contain millions of transistors and other circuit elements that are fabricated on a single silicon crystal substrate. For the device to be functional, a complex network of signal paths will normally be routed to connect the circuit elements distributed on the surface of the device. Efficient routing of these signals across the device can become more difficult as the complexity and number of the integrated circuits are increased. Thus, the formation of multi-level or multi-layered interconnection schemes such as, for example, dual damascene wiring structures, have become more desirable due to their efficacy in providing high speed signal routing patterns between large numbers of transistors on a complex semiconductor chip. Within the interconnection structure, metal vias run perpendicular to the silicon substrate and metal lines run parallel to the silicon substrate.

Presently, interconnect structures formed on an integrated circuit chip consists of at least about 2 to 8 wiring levels fabricated at a minimum lithographic feature size designated about 1× (referred to as “thinwires”) and above these levels are about 2 to 4 wiring levels fabricated at a width equal to about 2× and/or about 4× the minimum width of the thinwires (referred to as “fatwires”). In one class of structures, the thinwires are formed in a low dielectric constant (k) organosilicate (OSG) dielectric layer, and the fatwires are made in a silicon dioxide dielectric layer having a dielectric constant of about 4.

However, unlike silicon dioxide ILD structures, there are issues associated with retaining the original chemical and physical integrity of OSG materials as the “thinwire” structures are formed during single and dual damascene processing. Specifically, once the “thinwire” structure is formed, in typical “via-first” integration strategies, it is necessary to subsequently remove on the order of 100 to 300 nm of photoresist or organic material. Since the via and/or trench structure is present, the resist ash chemistry employed can potentially interact with the exposed OSG sidewalls and modify the material properties (which can also occur in some “trench-first” integration strategies where the OSG dielectric is also exposed to the ash chemistry employed). This modified layer can typically be removed leading to increased line-to-line capacitance and via resistance adversely affecting device performance and functionality. If this modified layer is not removed, there may be potential device reliability issues associated with these structures. It is, thus, necessary to utilize a resist ash process that induces minimal chemical and physical modification of the OSG sidewalls.

In view of the above, there is a need for providing an ash process that causes minimal damage to the ILD sidewalls. That is, a method is needed in which the ash process has minimal chemical reactivity with, as well as physical impact on, the OSG material.

### SUMMARY OF THE INVENTION

It is therefore an object of the present invention to provide a BEOL interconnect structure, e.g., a dual damascene type interconnect structure, in which the original physical and chemical properties of the dielectric are substantially unaltered during ashing in both the thinwire and fatwire levels.

It is a further object of the present invention to provide a BEOL interconnect structure in which both dielectric properties and feature profiles are substantially unaltered during post dual damascene wafer de-fluorination in both thinwire and fatwire levels.

It is an even further object of the present invention to provide a BEOL interconnect structure of improved device functionality, performance, and reliability owing to the reduced demand for removing modified dielectric material.

In keeping with these and other objects of the present invention, there is provided an interconnect structure comprising an organosilicate (OSG) low-k dielectric layer having a set of metallic lines formed therein such that the surface of the low-k dielectric that is in contact with the metallic lines has the original physical and chemical integrity of, and matches that of, a bulk low-k OSG material facilitating improved device characteristics. The term “low-k” as used in the present invention denotes an OSG dielectric material having a dielectric constant that is less than 4.0, preferably ˜2.7 to 3.1.

In broad terms, the present invention provides an interconnect structure that includes:
a semiconductor substrate comprising one or more device regions; and
one or more interconnect levels located atop the semiconductor substrate, said one or more interconnect levels comprising a patterned organosilicate dielectric having sidewalls, wherein said sidewalls are not substantially altered either chemically or physically.

In order to fabricate the above interconnect structure, a method is provided in which an in situ inert gas/H₂ plasma ash process is employed. In broad terms, the method of the present invention includes the steps of:
providing an interconnect structure comprising at least one organosilicate dielectric interlevel;
patterning the at least one organosilicate dielectric interlevel using a photoresist to provide at least one opening having sidewalls in said at least one organosilicate dielectric interlevel; and
removing the photoresist using an in-situ inert gas/H₂ ash process, said in-situ inert gas/H₂ ash process does not substantially alter the sidewalls of the organosilicate dielectric interlevel either chemically or physically.

The inert gas/H₂ ash processing step of the present invention is typically composed of about 90% or greater H₂ and about 10% or less of an inert gas such as Ar. Other typical and preferred operating conditions on one specific commercial etch platform are: 1 Torr chamber pressure, 500 sccm H₂ and 50 sccm Ar flow, 600 W 27 MHz (“source”) power and less than 50 W 2 MHz (“Bias”) Power. The method of the present invention can yield sufficiently quick strip rates (>120 nm/min) by operating at elevated pressures (1 Torr) and substrate temperatures with only marginal “bias” (substrate) power applied.

Since the plasma in the ash process of the present invention is typically about 90% or greater hydrogen, hydrogen atoms are the dominant radicals. Two direct routes of OSG material degradation through chemical reactivity include reactivity of exposed Si bonds created during ion impact to the surface and carbon removal from the OSG film.

In terms of Si reactivity, the chemisorptive-sticking coefficient on Si of hydrogen (<<0.001) is smaller than that of nitrogen (>0.05) and oxygen (>0.1). As such, a hydrogen-based ash process is likely to have reduced Si chemical reactivity with the OSG sidewall. On the issue of carbon removal, the reaction mechanism for the removal of carbon with oxygen and nitrogen based strip processes is via the formation of CO and CN species, respectively. Hydrogen based strip processes will likely form various CHₓ (x=1-3) species, which are less likely to be volatized than CO and CN, thus removing less carbon from the film.

Further, on commercial BEOL etch platforms, these ash processes run at pressures of greater than 200 mT, implying that the positive ion mean free path of less than 0.5 cm, i.e., less than the spacing between top and bottom electrodes of most BEOL commercial etch platforms. Ion scattering and, thus, ion impact on the OSG sidewalls likely causes physical damage to the OSG material. However, the dominant ion in these inert gas/H₂ plasmas, H+(1 amu), will probably cause less damage to the ILD sidewall than O+(16 amu) or N+(14 amu) because of it's much smaller mass.

The aforementioned physical and chemical properties of the in situ inert gas/H₂ processing step of the present invention, facilitates minimized dielectric modification during ashing consequent desirable device characteristics.

Another aspect of the present invention relates to an ash process which comprises the steps of:
positioning a substrate in a chamber;
supplying said chamber with an atmosphere of H₂ and an inert gas; and
forming a plasma in said chamber from said atmosphere whereby said substrate is exposed to said plasma.

### BRIEF DESCRIPTION OF THE DRAWINGS

FIG. 1 is a pictorial representation (through a cross sectional view) illustrating the interconnect structure of the present invention.

FIG. 2 is a cross sectional SEM showing ash-induced modification of a JSR 5109 porous OSG dielectric material utilizing a nitrogen-based de-fluorination process; this SEM is representative of a typical prior art process.

FIG. 3 is a cross sectional SEM showing no ash-induced modification of a JSR 5109 porous OSG dielectric material utilizing the inventive Ar/H₂ de-fluorination process.

### DETAILED DESCRIPTION OF THE INVENTION

The present invention which is directed to an interconnect structure useful for forming a semiconductor device, wherein the interconnect structure includes a dielectric material that has substantially unaltered physical and chemical properties facilitating improved device performance, functionality, and reliability as well as the method employed in fabricating the interconnect structure, will now be described in greater detail.

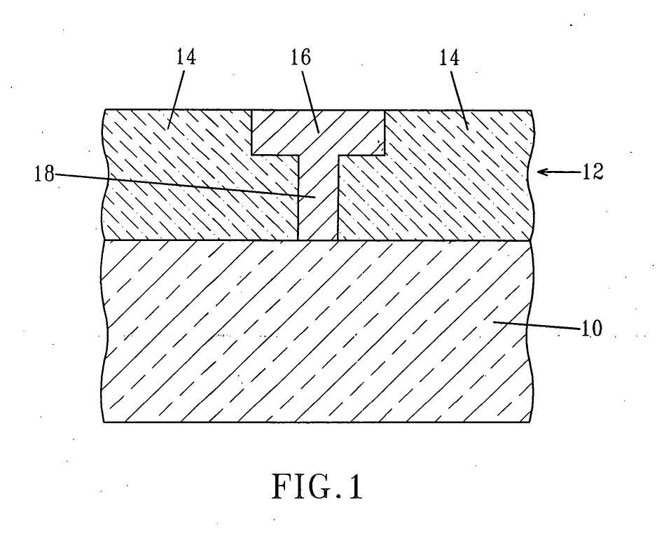

The interconnect structure of the present invention is shown, for example, in FIG. 1. The interconnect structure of FIG. 1 comprises a semiconductor substrate 10 which includes active device regions, such as field effect transistors (FETs), and isolation regions, such as shallow trench isolation regions or field oxide regions, either on the surface of the substrate or in the substrate itself. The active device regions and isolation regions are fabricated using techniques that are well known to those skilled in the art. One or more interconnect levels 12 comprising an organosilicate (OSG) dielectric 14 having metal lines 16 and vias 18 is formed atop the semiconductor substrate 10. The metal lines and vias are filled with a conductive metal such as, for example, Cu, Al, W, Pt and the like. Combinations and alloys of these conductive materials are also contemplated herein.

In the drawings, a single interconnect level is illustrated, but the present invention works equal well when a plurality of such interconnect levels are formed atop of each other.

The interconnect levels may be separated from each other by an etch stop layer or a diffusion barrier layer. A dielectric cap may be located atop each of the interconnect levels. For the sake of clarity, these various material layers of a typical interconnect structure are not shown in the drawings of the present application. The materials for the etch stop layers, diffusion barrier layers and dielectric caps are well known to those skilled in the art as well.

The interconnect structure shown in FIG. 1 is formed using a single or dual damascene process. The OSG dielectric is formed on the surface of a semiconductor substrate by spin-on coating or a similar deposition process such as chemical vapor deposition. The metal lines and vias 16 are formed by lithography, etching and filling the etched regions with a conductive material. The lithographic step includes applying a photoresist to the OSG dielectric, exposing the photoresist to a pattern of radiation and developing the exposed photoresist utilizing a conventional resist developer to provide a patterned photoresist. The etching step used in the present invention in forming the line and via openings includes a dry etching process such as reactive ion etching, laser ablation, ion beam etching or plasma etching that selectively removes exposed portions of the OSG dielectric as compared to the photoresist.

After providing the openings, i.e., lines and/or vias, the patterned photoresist is typically removed utilizing an inert gas/H₂ ash process, which will be described in greater detail hereinbelow. Next, conductive material is formed within the line and via openings utilizing a deposition process such as, for example, sputtering, chemical vapor deposition, chemical solution deposition, physical vapor deposition and the like. The conductive material used to fill the openings includes, but is not limited to: W, Al, Cu, Pt, and mixtures, alloys or multilayers thereof.

In some embodiments of the present invention, a diffusion barrier is formed within each line or via opening prior to deposition of the conductive material. A planarization process, such as chemical mechanical polishing (CMP) or grinding, typically follows the deposition of the conductive material.

The formation of the interconnect structure depicted in FIG. 1 is made feasible by utilizing an in situ inert gas/H₂ ash process post via and trench processing in a single or dual damascene scheme that induces minimal chemical and physical modification of the OSG sidewalls. The inert gas/H₂ ash process of the present invention is capable of removing the patterned photoresist without negatively affecting the sidewalls of the openings etched above. In accordance with the present invention, the ash process of the present invention is formed in the same reactor as that used to provide the at least one openings, i.e., lines or vias, into the organosilicate dielectric interlevel.

The inert gas/H₂ ash process of the present invention is typically composed of a plasma comprising about 90% or greater H₂ and about 10% or less of an inert gas. More preferably, the inert gas/H₂ ash process comprises from about 90 to about 99.99% H₂ and from about 10 to about 0.01% inert gas. Other typical operating conditions that can be employed on one typical commercial etch platform are: a chamber pressure of from about 0.75 to about 1 Torr, with a 1 Torr chamber pressure being highly preferred, a flow rate of from about 450 to about 500 sccm H₂ and from about 10 to about 50 sccm inert gas, with a flow rate of 500 sccm H₂ and 50 sccm inert gas being more preferred, a source power of from about 450 to about 600 W, with a 600 W 27 MHz (“Source”) power being more highly preferred, and less than about 50W 2 MHz (“Bias”) power.

The conditions employed in the present invention are capable of converting the inert gas/H₂ atmosphere into a plasma which is used to remove the photoresist from a structure. The plasma is generated using any conventional plasma generating source such as, for example, a dual frequency capacitively-coupled plasma discharge source.

The term “inert gas” is used in the present invention to denote a gas containing at least one element from VIIIA of the Periodic Table of Elements. Illustrative examples of inert gases that can be employed in the ash processing step of the present invention include He, Ne, Ar, Kr, Xe and mixtures thereof. Of the various inert gases mentioned above, it is preferred to employ Ar alone, or Ar in combination with any of the other inert gases.

The ash process yields sufficiently quick strip rates (>120 nm/min) by operating at elevated pressures and substrate temperatures with only marginal “bias” (substrate) power applied. During the ash processing step of the present invention, the substrate temperature is typically maintained at a temperature of about 20° C. or above. More preferably, the substrate temperature during the ash process is maintained at a temperature from about 20° to about 25° C.

This inert gas/H₂ ash processing step of the present invention removes the patterned photoresist while, minimizing the chemical and physical reactivity with OSG materials owing to its inherent chemical make up. For example, H-radicals are unable to achieve an efficient chemical reactivity with Si and carbon within the OSG dielectric film compared with other conventional ash chemistries and the minute ionic mass H⁺ ions ensures minimal physical damage during ion scattering occurring in the ash process.

As a consequence of such a chemically and physically “friendly” ash process, the original chemical and physical integrity of the OSG material is maintained, eliminating the need for removing a modified OSG layer and, further, facilitating improved device performance, functionality and reliability.

Further, the characteristics of the inventive process enables its use for post dual damascene wafer de-flourination (DF). In a dual damascene flow, the cap (barrier) open process occurs subsequent to ashing the photoresist or organic material; it is possible, in such an instance, that there may be fluoropolymer deposits located on the wafer surface due to the fluorine-containing chemistries employed for the cap open (etch) process. The inert nature of the inert gas/H₂ ash chemistry makes it suitable for removing these fluoropolymer deposits that may have accrued during the cap etch process, this process is referred to as de-fluorination (DF).

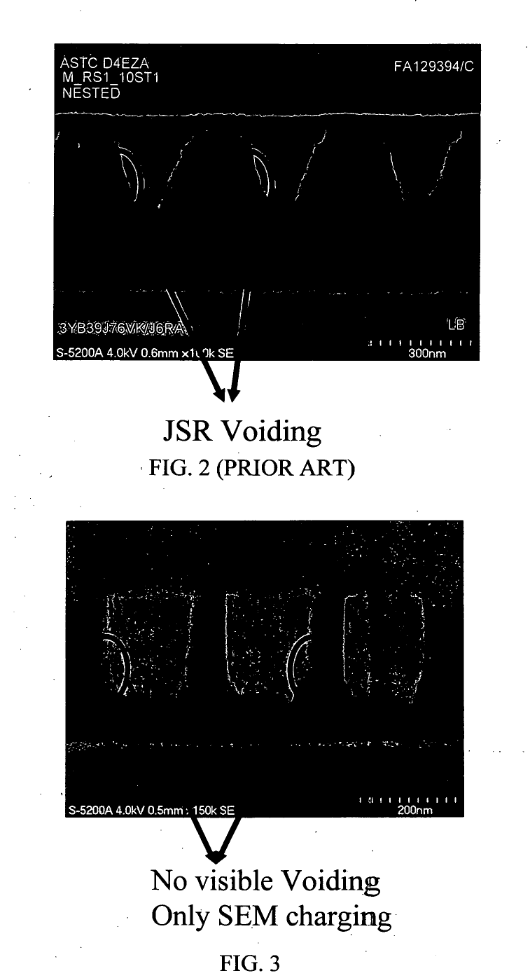

FIGS. 2 and 3 are actual SEM images showing a porous OSG material exposed to both a nitrogen-based ash process (FIG. 2) and the inert gas/H₂ ash process of the present invention during the de-fluorination step of a M1 single damascene process. The SEM in FIG. 2, which is representative of the prior art, clearly shows “voiding” in the porous OSG material exposed to a typical nitrogen-based ashing process. In the SEM image of FIG. 2, the inert gas/H₂ ash process of the present invention did not cause formation of any visible voids. In this example, Ar/H₂ was used as the ashing agent. These SEM images were obtained for a beam voltage of 4 kV with minimal focus time on the sample. These SEM conditions ensure minimal ILD film shrinkage and no void formation within the film. The images thus illustrate the effect of ash chemistry on film (porous OSG) modification.

While the present invention has been particularly shown and described with respect to preferred embodiments thereof, it will be understood by those skilled in the art that the foregoing and other changes in forms and details may be made without departing from the scope and spirit of the present invention. It is therefore intended that the present invention not be limited to the exact forms and details described and illustrated, but fall within the scope of the appended claims.

1. An interconnect structure comprising:
a semiconductor substrate comprising one or more device regions; and
one or more interconnect levels located atop the semiconductor substrate, said one or more interconnect levels comprising a patterned organosilicate dielectric having sidewalls, wherein said sidewalls are not substantially altered either chemically or physically.

2. The interconnect structure of claim 1 wherein said patterned organosilicate dielectric has a dielectric constant of less than 4.0.

3. The interconnect structure of claim 1 wherein said one or more interconnect levels include metal lines and vias.

4. The interconnect structure of claim 3 wherein the metal lines and vias comprise a conductive material.

5. The interconnect structure of claim 1 wherein said one or more interconnect levels form a thinwire interconnect structure.

6. The interconnect structure of claim 1 wherein said one or more interconnect levels form a thinwire interconnect structure.

7. The interconnect structure of claim 1 wherein said one or more device regions comprise a field effect transistor.

8. A process of fabricating a patterned organosilicate dielectric comprising:
providing an interconnect structure comprising at least one organosilicate dielectric interlevel;
patterning the at least one organosilicate dielectric interlevel using a photoresist to provide at least one opening having sidewalls in said at least one organosilicate dielectric interlevel; and
removing the photoresist using an in-situ inert gas/H₂ ash process, said in-situ inert gas/H₂ ash process does not substantially alter the sidewalls of the at least one opening either chemically or physically.

9. The process of claim 8 wherein said inert gas comprises He, Ne, Xe, Ar, Kr, Xe or mixtures thereof.

10. The process of claim 8 wherein said inert gas is He.

11. The process of claim 8 wherein said inert gas/H₂ ash process is carried out in a plasma.

12. The process of claim 1 1 wherein the plasma comprises about 90% or greater H₂ and about 10% or less of inert gas.

13. The process of claim 12 wherein the plasma comprises about 90 to about 99.99% H₂ and about 10 to about 0.01% of inert gas.

14. The process of claim 8 wherein the inert gas/H₂ ash process is carried out at a pressure of about 0.75 to about 1 Torr, a flow rate of about 450 to about 500 sccm H₂ and from about 10 to about 50 sccm inert gas, a source power of from about 450 to about 600 W, and a bias power of less than about 50W.

15. An ash process comprising the steps of:
positioning a substrate in a chamber;
supplying said chamber with an atmosphere of H₂ and an inert gas; and
forming a plasma in said chamber from said atmosphere whereby said substrate is exposed to said plasma.

16. The process of claim 15 wherein said inert gas comprises He, Ne, Xe, Ar, Kr, Xe or mixtures thereof.

17. The process of claim 15 wherein said inert gas is He.

18. The process of claim 15 wherein said inert gas/H₂ ash process is carried out in a plasma.

19. The process of claim 15 wherein the plasma comprises about 90% or greater H₂ and about 10% or less of inert gas.

20. The process of claim 15 wherein the inert gas/H₂ ash process is carried out at a pressure of about 0.75 to about 1 Torr, a flow rate of about 450 to about 500 sccm H₂ and from about 10 to about 50 sccm inert gas, a source power from about 450 to about 600 W, and a bias power of less than about 50W.
